(19) United States
(12) Patent Application Publication
(10) Pub. No.: US 2020/0075491 A1
(43) Pub. Date: Mar. 5, 2020

(54) MICROELECTRONIC DEVICES DESIGNED WITH PACKAGE INTEGRATED TUNABLE FERROELECTRIC CAPACITORS

(71) Applicant: Intel Corporation, Santa Clara, CA (US)

(72) Inventors: Georgios C. DOGIAMIS, Chandler, AZ (US); Feras EID, Chandler, AZ (US); Thomas L. SOUNART, Chandler, AZ (US); Aleksandar ALEKSOV, Chandler, AZ (US); Johanna M. SWAN, Scottsdale, AZ (US)

(21) Appl. No.: 16/611,841

(22) PCT Filed: Jun. 30, 2017
(86) PCT No.: PCT/US2017/040417

§ 371 Date: Nov. 7, 2019

(51) Int. Cl. H01L 23/538; H01L 23/64; H01G 7/06; H01L 27/01

(52) U.S. Cl. CPC H01L 23/5383; H01L 23/5385; H01L 27/01; H01L 23/645; H01G 7/06; H01L 23/642

(57) ABSTRACT

Embodiments of the invention include a microelectronic device that includes a plurality of organic dielectric layers and a tunable ferroelectric capacitor formed in-situ with at least one organic dielectric layer of the plurality of organic dielectric layers. The tunable ferroelectric capacitor (e.g., varactor) includes first and second conductive electrodes and a ferroelectric layer that is positioned between the first and second conductive electrodes.

### FIELD OF THE INVENTION

Embodiments of the present invention relate generally to the manufacture of semiconductor devices. In particular, embodiments of the present invention relate to microelectronic devices that are designed with package integrated tunable ferroelectric capacitors.

### BACKGROUND OF THE INVENTION

Small form factor electronic systems are needed for internet of things devices (IOT), mobile devices, wearables, and autonomous vehicles. Since package area is limited in these systems, capacitors typically require high capacitance densities (e.g., 10-10,000 nF/mm2), which requires high-k dielectric materials. The dielectric materials used typically require annealing, sintering, or deposition at greater than 500 degrees C.

Tunable capacitors using high dielectric constant ferroelectric materials have been utilized in many microwave devices for several years, such as, phase shifters, tunable filters, phased array antennas, etc. For practical usage of ferroelectric varactors, it is desirable to have large tunability as well as low device losses. Moreover, high dielectric constants have to be achieved in the ferroelectric layers in order to enable large capacitance values in a small area. Such tunable capacitors typically are fabricated using expensive semiconductor manufacturing processes including RF sputtering, MOCVD, CCVD, sol-gel, or pulsed laser ablation etc. and substrates (e.g., silicon or ceramic). Typical epitaxially-grown high dielectric constant ferroelectric layers used today are strontium titanate (STO) and or barium strontium titanate (BST).

### BRIEF DESCRIPTION OF THE DRAWINGS

FIG. 1 illustrates a microelectronic device having package integrated tunable high-k ferroelectric capacitors and a substrate in accordance with one embodiment.

FIG. 2 illustrates a microelectronic device having a package substrate with package integrated high-k ferroelectric capacitors in a vertical configuration in accordance with one embodiment.

FIG. 3 illustrates a microelectronic device having a package substrate with package integrated high-k ferroelectric capacitors in accordance with one embodiment.

FIG. 4A illustrates a top view of a microelectronic device having a package substrate with package integrated high-k ferroelectric capacitors in accordance with one embodiment.

FIG. 4B illustrates a cross-sectional view AA′ of a microelectronic device having a package substrate with package integrated high-k ferroelectric capacitors in accordance with one embodiment.

FIG. 5A illustrates a top view of a microelectronic device having a package substrate with package integrated high-k ferroelectric capacitors in accordance with one embodiment.

FIG. 5B illustrates a cross-sectional view AA′ of a microelectronic device having a package substrate with a package integrated high-k ferroelectric capacitor 580 in accordance with one embodiment.

FIG. 6 illustrates a computing device 1000 in accordance with one embodiment.

### DETAILED DESCRIPTION OF THE INVENTION

Described herein are microelectronic devices that are designed with package integrated tunable ferroelectric capacitors. In the following description, various aspects of the illustrative implementations will be described using terms commonly employed by those skilled in the art to convey the substance of their work to others skilled in the art. However, it will be apparent to those skilled in the art that embodiments of the present invention may be practiced with only some of the described aspects. For purposes of explanation, specific numbers, materials and configurations are set forth in order to provide a thorough understanding of the illustrative implementations. However, it will be apparent to one skilled in the art that embodiments of the present invention may be practiced without the specific details. In other instances, well-known features are omitted or simplified in order to not obscure the illustrative implementations.

Various operations will be described as multiple discrete operations, in turn, in a manner that is most helpful in understanding embodiments of the present invention, however, the order of description should not be construed to imply that these operations are necessarily order dependent. In particular, these operations need not be performed in the order of presentation.

Currently, the need for tunable communication systems has become even more apparent with the co-existence of several communication protocols on a single device (e.g., BlueTooth, WiFi, 3G, 4G/LTE, 5G) and amplified by the fact that different geographic locations (e.g., EU, USA, China, Korea, Japan) have different communication band requirements. For example in today's telecommunication devices, more than 10×10 mm² on package/PCB area is consumed by filters and switches to enable the 10 or more different bands that are allocated. Introducing tunable elements in such area sensitive systems would be highly desirable. Moreover low cost fabrication techniques of those would be advantageous for their wide adoption.

The present design addresses the fabrication of tunable ferroelectric capacitors (i.e., varactors) within a low-temperature organic semiconductor package substrate that is compatible with high volume package substrate fabrication technology. This present design is based on a demonstrated ability to deposit perovskite ferroelectric materials in the package substrate. The present design allows the fabrication of tunable ferroelectric capacitors (i.e., varactors) utilizing substrate manufacturing technology. These varactors include stacks of high dielectric constant ferroelectric materials (e.g., lead zirconate titanate (PZT), sodium potassium niobate (KNN), barium titanate (BTO), or other materials) disposed between metal electrodes. These electrodes can be used to apply a DC and RF voltage to the ferroelectric layer. Applying a DC voltage across the electrodes produces a stress in the ferroelectric material, causing the change of polarization, and thus the change of its dielectric properties. This in turn changes the capacitance of the stack that the RF signal (voltage) will encounter through its path. In other words, varying the DC voltage level would lead to different capacitance encountered by the RF signal. Typically there is an approximate square law dependence between the capacitance and the applied DC voltage. Compared to traditional varactors (diodes) the capacitance change is more gradual with varying DC voltage.

The present design results in package-integrated tunable ferroelectric capacitors (i.e., varactors), thus enabling reconfigurable systems. Since the capacitors are embedded within the existing package layers, this present design leads to systems with reduced form-factors, i.e., reduced area and thickness. This present design can be manufactured as part of the substrate fabrication process and as such could reduce or even eliminate the need for discrete varactor components. It is therefore a high volume manufacturable solution, which may reduce the cost of electronic systems in package while enabling tunability such as tunable RF filters, phased arrays, etc.

The present design includes a high-k ferroelectric capacitor that is fabricated directly in-situ on a low-temperature organic substrate or in a low-temperature organic substrate to form a package-integrated capacitor with low Z-height and no assembly required. The capacitor fabrication can also be integrated into the existing package substrate layers, thus freeing up land-side area for input output (IO) and power bumps, and eliminating Z-height entirely for the integrated capacitor.

The present design utilizes thin films of crystalline high-k dielectric material (e.g., ferroelectric material, ferroelectric perovskite, lead zirconate titanate (PZT), barium strontium titanate (BST), barium titanate (BTO), sodium potassium niobate (KNN), etc.), that is deposited on one or more of the layers in an organic package substrate to act as the dielectric layer of a substrate-integrated capacitor. The deposition is carried out at substrate-compatible temperatures, using, for example, pulsed laser anneal to crystallize the dielectric film while keeping the substrate at low temperatures (e.g., less than 215 degrees C.) to prevent damaging the organic layers. After patterning the capacitor dielectric thin film, an electrode layer is deposited and patterned.

Discrete capacitors require several assembly steps to attach them to the substrate, including flux deposition, individual component pick and place, mass reflow, and optionally deflux to remove any flux residue. These assembly steps add process time and cost. Pick and place of capacitors is a serial process of many capacitors on each die, and this becomes increasingly expensive and difficult as capacitors are scaled down to sub-millimeter dimensions. In the present design, none of these assembly steps are required. The capacitor is manufactured as part of the substrate fabrication.

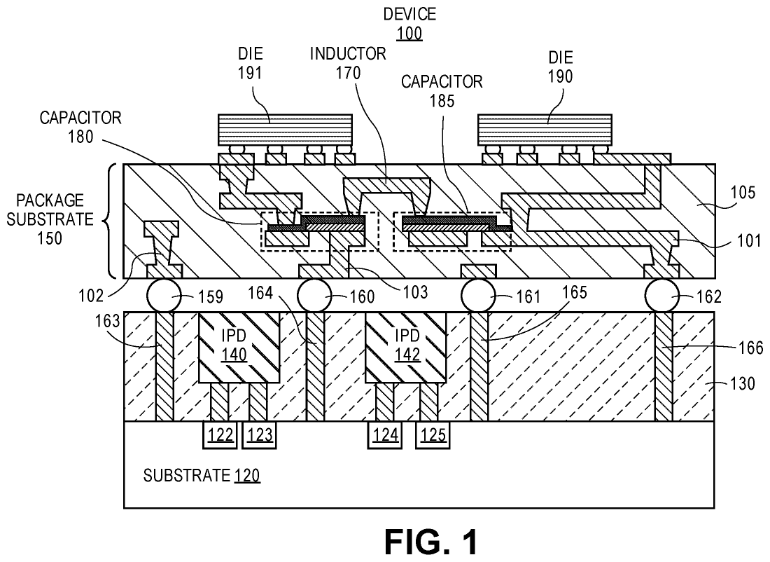

FIG. 1 illustrates a microelectronic device having package integrated tunable high-k ferroelectric capacitors and a substrate in accordance with one embodiment. The microelectronic device 100 includes an optional substrate 120 and a package substrate 150 having high-k ferroelectric capacitors. The package substrate 150 includes integrated tunable high-k ferroelectric capacitors 180 and 185, conductive layers (e.g., 101, 102, 103), and dielectric material 105 (e.g., organic material, low temperature co-fired ceramic materials, liquid crystal polymers, etc.). The capacitor 180 includes a ferroelectric stack including conductive upper and lower electrodes and high-k ferroelectric layer that is disposed between the conductive electrodes. The capacitor 185 includes a ferroelectric stack including conductive upper and lower electrodes and high-k ferroelectric layer that is disposed between the conductive electrodes. An inductor 170 is electrically coupled to upper electrodes of the capacitors.

The components 122-125 of the substrate 120 and Integrated Passive Devices (IPDs) 140 and 142 can communicate with components of the substrate 150 or other components not shown in FIG. 1 using connections 163-166 and solder balls 159-162. The IPDs may include any type of passives including inductors, transformers, capacitors, and resistors. In one example, capacitors on the IPD die may be used for power delivery. In another example, resistors on the same or a different IPD may be used for digital signal equalization. In another example, the substrate 120 is a printed circuit board.

The capacitors 180 and 185 can be created in-situ during substrate manufacturing as part of the build up layers of the substrate 150. The capacitors 180 and 185 can also be coupled to the dies 191 and 190, respectively.

The present design utilizes package-integrated ferroelectric structures (e.g., 180, 185) to act as RF tunable capacitors. The capacitor stack includes a ferroelectric material between patterned metal electrodes. Applying a DC voltage across the electrodes changes a spontaneous polarization of the ferroelectric material, and thus the layer's dielectric properties. This in turn changes the effective capacitance of the stack that the RF signal (i.e., RF voltage applied at the same metal electrodes) will encounter thru its path.

Varying the DC voltage level would tune the capacitance encountered by the RF signal. In one example, typical tuning ratios (e.g., maximum capacitance: minimum capacitance) are from 1.01 to 3. Capacitor electrode sizes may range from 4 um² up to several hundreds of um² which would provide capacitance values ranging from hundreds of femtofarads (fF) to nanofarad (nF) values. Typical package layer thickness may range from 2 um to 50 um. Ferroelectric layer thicknesses may range from below 30 nanometers (nm) to lum. Metal electrode thicknesses may range from 1 um to 15 um.

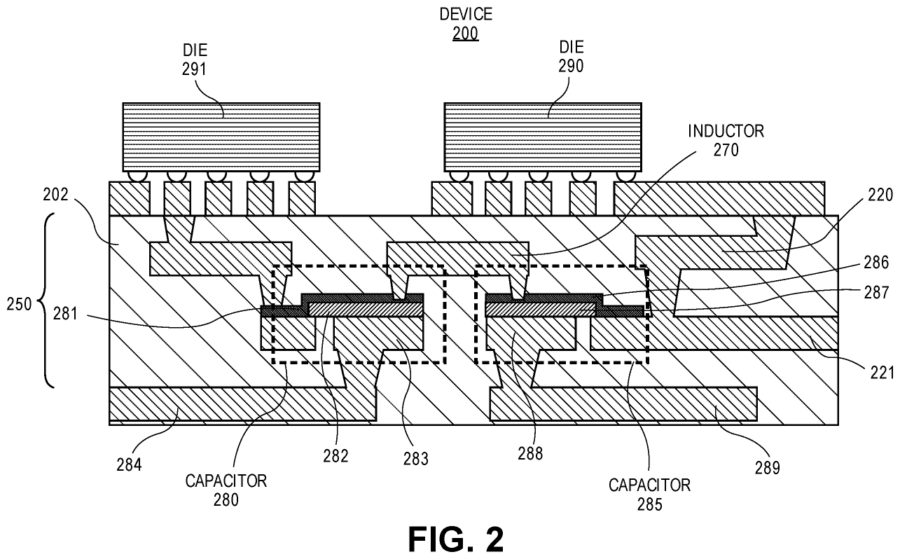

FIG. 2 illustrates a microelectronic device having a package substrate with package integrated high-k ferroelectric capacitors in a vertical configuration in accordance with one embodiment. The microelectronic device 200 includes a package substrate 250 having tunable high-k ferroelectric capacitors 280 and 285, dielectric material 202 (e.g., organic material, low temperature co-fired ceramic materials, liquid crystal polymers, etc.) that includes organic layers, and different levels of conductive layers 220, 221, 284, and 289 and connections. The capacitor 280 includes conductive electrodes 281 and 283 and a high-k ferroelectric layer 282. The parallel-plate capacitor 280 is embedded in the organic package substrate 250 and electrically routed with the standard conductive layers and connections in the package substrate. The capacitor 285 includes conductive electrodes 286 and 288 and a high-k ferroelectric layer 287. An optional inductor 270 is electrically coupled to upper electrodes of the capacitors in this example. At least one capacitor is used to form different types of filter structures (e.g., filter inductor capacitor (LC) network, filter capacitor inductor capacitor (CLC) network, etc.) The conductive electrodes of the capacitors can include the same material (e.g., Copper) or include different conductive material.

The multilayer package substrate 250 includes several integrated circuits including dies 290 and 291. The package substrate has multiple conductive metal layers that can be used to form components such as inductors, transformers and transmission lines. In addition the substrate may contain areas within one or more layers that contain a ferroelectric material. The ferroelectric material may be patterned as needed and in conjunction with the metal interconnect structures form package integrated varactors, i.e., variable/ tunable capacitors.

The integrated circuits (e.g., dies 290, 291) may include any circuit found in a communication module such as CPU, application processors, transceiver, power amplifiers, low noise amplifiers, baseband circuitry and or switches. The key components used in the front-end modules (e.g., baluns, filters, matching networks) may each include one or more tunable components that utilize a ferroelectric tunable device. As shown in FIG. 2, a filter capacitor inductor capacitor (CLC) network may be used between any 2 chips (e.g., dies 290 and 291) and may utilize several fixed and tunable components in the package substrate. It is to be appreciated that in this example only 2 shunt tunable elements are shown but other configurations may include more tunable elements and other interconnection schemes, for example, series tunable elements. Other interconnections may include series or parallel LC sections and interconnections thereof. The capacitors may share a common bottom electrode. In the configuration shown in FIG. 2 one of the electrodes is thin (top) while the other is thicker (bottom). It is however appreciated that both electrodes can be thick or thin depending on the required series resistance (ESR) set by the application.

In one example, the high-k material (e.g., ferroelectric material, ferroelectric perovskite, lead zirconate titanate (PZT), barium strontium titanate (BST), barium titanate (BTO), sodium potassium niobate (KNN), etc.) can be any material with permittivity high enough to achieve a capacitance density in the range of 10-10,000 nF/mm². The high-k ferroelectric layer can be deposited directly on a metal layer (e.g., copper) of the package substrate or on a conductive seed layer of another material. The thickness of the high-k ferroelectric layer can range from about 30 nanometers (nm) to 1000 nm, while the relative permittivity will range from at least 200 up to as high as 10,000, but typically will be in the range of 1000 to 5000.

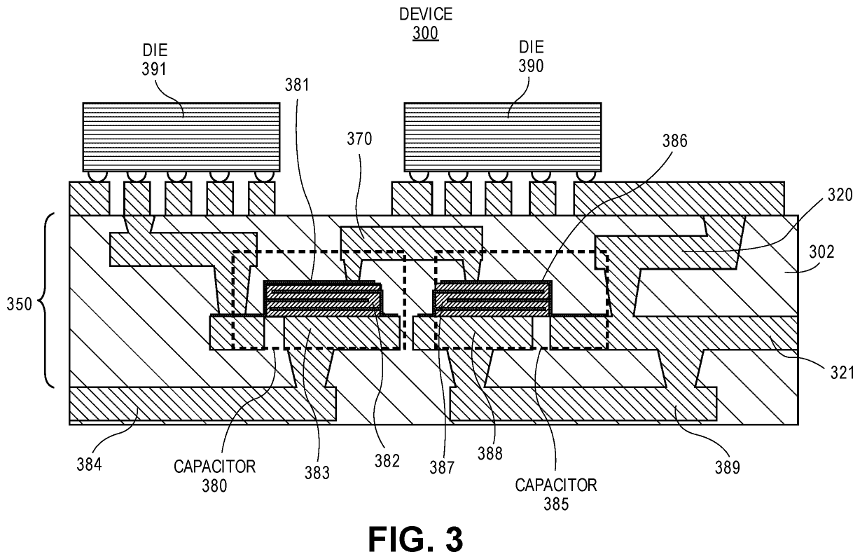

FIG. 3 illustrates a microelectronic device having a package substrate with package integrated high-k ferroelectric capacitors in accordance with one embodiment. The microelectronic device 300 includes a package substrate 350 having tunable high-k ferroelectric capacitors 380 and 385, dielectric material 302 (e.g., organic material, low temperature co-fired ceramic materials, liquid crystal polymers, etc.) that includes organic layers, and different levels of conductive layers 320, 384, 321 and 389 and connections. The capacitor 380 includes conductive electrodes 381 and 383 and a high-k ferroelectric material 382. The parallel-plate capacitor 380 is embedded in the organic package substrate 350 and electrically routed with the standard conductive layers and connections in the package substrate. The capacitor 385 includes conductive electrodes 386 and 388 and a high-k ferroelectric material 387. An optional inductor 370 is electrically coupled to upper electrodes of the capacitors. In FIG. 3, the tunable capacitors may include multiple layers of ferroelectric materials and thin electrodes 381 and 386.

Alternatively to the thin metal layers illustrated in FIG. 3 that allow a multi-layer capacitor to fit within a single substrate layer, the interconnect metallization can be thick and hence several capacitor layers can be distributed within several substrate layers. In that sense each package substrate layer can contain a single or two or three (or more) capacitor layer stacks and this can propagate through 2 or 3 (or more) substrate layers, forming a capacitor that in total has many more stacked layers than if it were confined to a single substrate layer. Also a combination of what is mentioned in this section and what is illustrated in FIG. 3 is possible and this depends on the capacitance value required, and the substrate area and z-height that are available for the tunable capacitor.

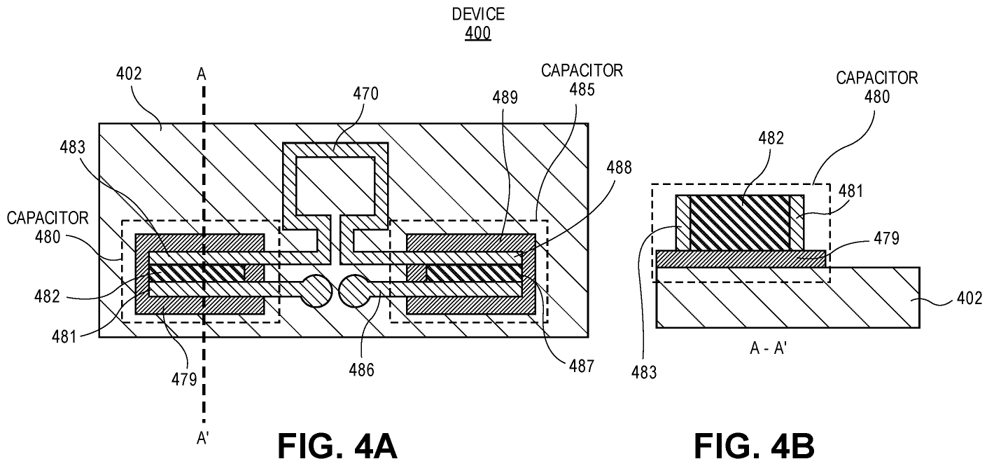

The capacitor stack can also include a sandwich configuration in which the ferroelectric material is deposited between two electrodes in the horizontal direction as shown in FIGS. 4A and 4B in accordance with one embodiment. FIG. 4A illustrates a top view of a microelectronic device having a package substrate with package integrated high-k ferroelectric capacitors in accordance with one embodiment. The microelectronic device 400 includes a package substrate 450 having tunable high-k ferroelectric capacitors 480 and 485, dielectric material 402 (e.g., organic material, low temperature co-fired ceramic materials, liquid crystal polymers, etc.) that includes organic layers, and different levels of conductive layers and connections. The capacitor 480 includes conductive electrodes 481 and 483 and a high-k ferroelectric layer 482. The parallel-plate capacitor 480 is embedded in the organic package substrate 450 and electrically routed with the standard conductive layers and connections in the package substrate. The capacitor 485 includes conductive electrodes 486 and 488 and a high-k ferroelectric layer 487. An optional inductor 470 is electrically coupled to upper electrodes of the capacitors (inductor bias lead not shown in figure). A DC tuning voltage can be applied between the electrodes 483 and 481, or between the electrodes 486 and 488 to tune the capacitance of 485 and 480, respectively. The substrate includes an optional passivation material 479 and 489.

FIG. 4B illustrates a cross-sectional view AA′ of a microelectronic device having a package substrate with package integrated high-k ferroelectric capacitors in accordance with one embodiment. In this configuration, the electrodes are patterned in the same horizontal layer. In this case, applying a DC voltage across the electrodes in the horizontal plane causes the polarization of the ferroelectric material (e.g., 482, 487) to change, and thus again a capacitance change.

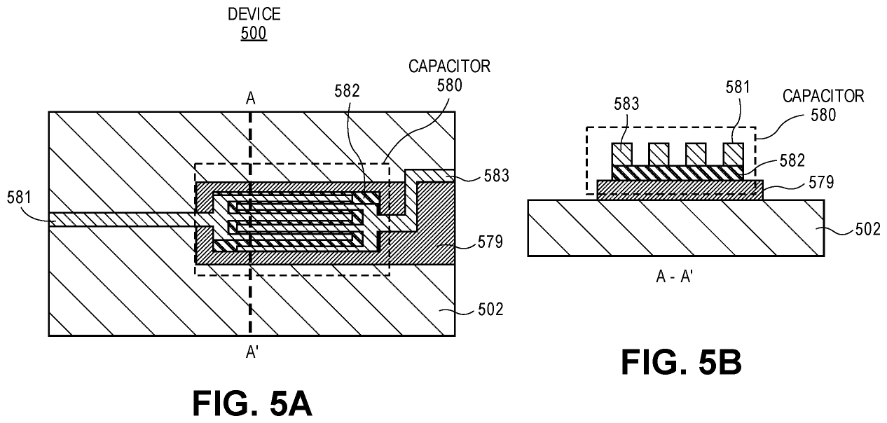

Alternatively, the capacitor ferroelectric stack may include an interdigitated configuration as shown in FIGS. 5A and 5B in accordance with one embodiment. In this configuration, the electrodes are patterned in the same horizontal layer in an interdigitated fashion. In this case, applying a DC voltage across the electrodes will tune the capacitance value of the capacitor stack.

FIG. 5A illustrates a top view of a microelectronic device having a package substrate with package integrated high-k ferroelectric capacitors in accordance with one embodiment. The microelectronic device 500 includes a package substrate having a tunable high-k ferroelectric capacitor 580, dielectric material 502 (e.g., organic material, low temperature co-fired ceramic materials, liquid crystal polymers, etc.) that includes organic layers, and different levels of conductive layers and connections. The capacitor 580 includes conductive electrodes 581 and 583 and a high-k ferroelectric layer 582. The substrate includes an optional passivation material 579.

FIG. 5B illustrates a cross-sectional view AA′ of a microelectronic device having a package substrate with a package integrated high-k ferroelectric capacitor 580 in accordance with one embodiment.

The package substrates and capacitors can have different thicknesses, length, and width dimensions in comparison to those disclosed and illustrated herein. In another embodiment, any of the devices or components can be coupled to each other.

Other embodiments might include tunable voltage controlled oscillators and phase shifters. Other embodiments might include reconfigurable RF matching networks. Other embodiments might include the creation of reconfigurable diplexers/triplexers etc. Diplexers are typically used with radio receivers or transmitters on different, widely separated, frequency bands.

It will be appreciated that, in a system on a chip embodiment, the die may include a processor, memory, communications circuitry and the like. Though a single die is illustrated, there may be none, one or several dies included in the same region of the wafer.

In one embodiment, the microelectronic device may be a crystalline substrate formed using a bulk silicon or a silicon-on-insulator substructure. In other implementations, the microelectronics device may be formed using alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-V or group IV materials. Although a few examples of materials from which the substrate may be formed are described here, any material that may serve as a foundation upon which a semiconductor device may be built falls within the scope of embodiments of the present invention.

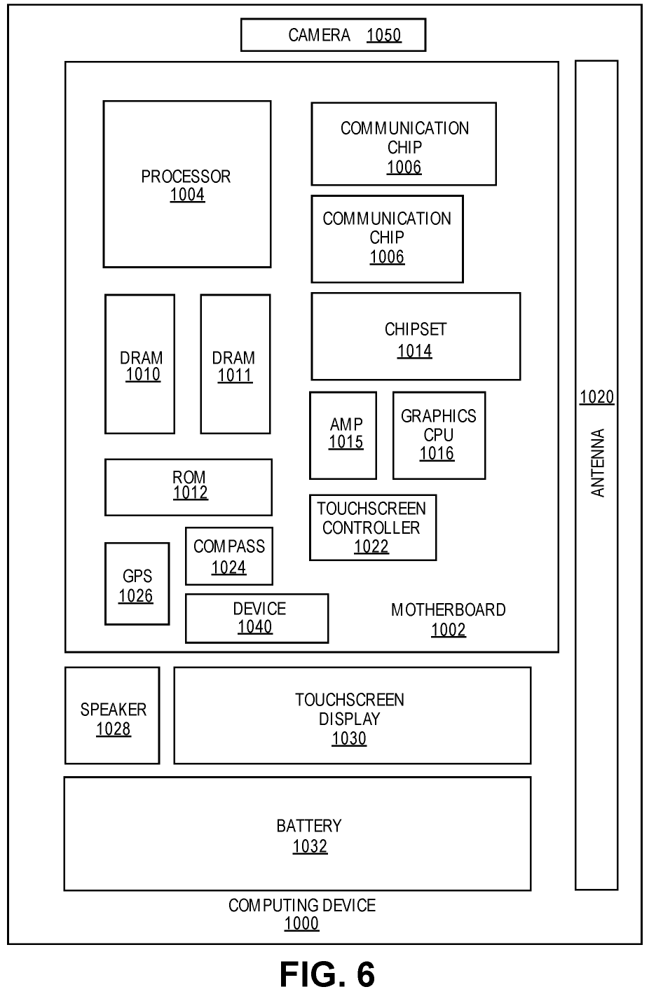

FIG. 6 illustrates a computing device 1000 in accordance with one embodiment. The computing device 1000 houses a board 1002. The board (e.g., motherboard, printed circuit board, etc.) may include a number of components, including but not limited to at least one processor 1004 and at least one communication chip 1006. The at least one processor 1004 is physically and electrically coupled to the board 1002. In some implementations, the at least one communication chip 1006 is also physically and electrically coupled to the board 1002. In further implementations, the communication chip 1006 (e.g., microelectronic device 100, 200, 300, 400, 500, etc.) is part of the processor 1004.

Depending on its applications, computing device 1000 may include other components that may or may not be physically and electrically coupled to the board 1002. These other components include, but are not limited to, volatile memory (e.g., DRAM 1010, 1011), non-volatile memory (e.g., ROM 1012), flash memory, a graphics processor 1016, a digital signal processor, a crypto processor, a chipset 1014, an antenna unit 1020, a display, a touchscreen display 1030, a touchscreen controller 1022, a battery 1032, an audio codec, a video codec, a power amplifier 1015, a global positioning system (GPS) device 1026, a compass 1024, a gyroscope, a speaker, a camera 1050, and a mass storage device (such as hard disk drive, compact disk (CD), digital versatile disk (DVD), and so forth).

The communication chip 1006 enables wireless communications for the transfer of data to and from the computing device 1000. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1006 may implement any of a number of wireless standards or protocols, including but not limited to Wi-Fi (IEEE 802.11 family), WiMAX (IEEE 802.16 family), WiGig, IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 1000 may include a plurality of communication chips 1006. For instance, a first communication chip 1006 may be dedicated to shorter range wireless communications such as Wi-Fi, WiGig, and Bluetooth and a second communication chip 1006 may be dedicated to longer range wireless communications such as GPS, EDGE, GPRS, CDMA, WiMAX, LTE, Ev-DO, 5G, and others.

The at least one processor 1004 of the computing device 1000 includes an integrated circuit die packaged within the at least one processor 1004. In some embodiments of the invention, the processor package includes one or more devices, such as microelectronic devices (e.g., microelectronic device 100, 200, 300, 400, 500, etc.) having a package integrated ultra-high-k capacitor in accordance with implementations of embodiments of the invention. The term “processor” may refer to any device or portion of a device that processes electronic data from registers and/or memory to transform that electronic data into other electronic data that may be stored in registers and/or memory.

The communication chip 1006 also includes an integrated circuit die packaged within the communication chip 1006. In accordance with another implementation of embodiments of the invention, the communication chip package includes one or more microelectronic devices (e.g., microelectronic device 100, 200, 300, 400, 500, etc.) having package-integrated high-k ferroelectric capacitors.

The following examples pertain to further embodiments. Example 1 is a microelectronic device that includes a plurality of organic dielectric layers and a tunable ferroelectric capacitor formed in-situ with at least one organic dielectric layer of the plurality of organic dielectric layers and the ferroelectric capacitor includes first and second conductive electrodes and a ferroelectric layer that is positioned between the first and second conductive electrodes.

In example 2, the subject matter of example 1 can optionally include an inductor that is electrically coupled to one of the first and second electrodes.

In example 3, the subject matter of any of examples 1-2 can optionally include the the ferroelectric capacitor that comprises a high-k capacitor having a tunable capacitance based on applying a voltage across the first and second electrodes to cause a change in polarization of the ferroelectric layer and thus a change in dielectric properties of the ferroelectric layer.

In example 4, the subject matter of any of examples 1-3 can optionally include the tunable capacitance of the ferroelectric capacitor that enables a reconfigurable microelectronic device.

In example 5, the subject matter of any of examples 1-4 can optionally include the tunable capacitance of the ferroelectric capacitor has a tuning ratio of maximum capacitance to minimum capacitance that is approximately 1.01 to 3

In example 6, the subject matter of any of examples 1-5 can optionally include the ferroelectric layer that comprises at least one of ferroelectric material, ferroelectric perovskite, lead zirconate titanate (PZT), barium strontium titanate (BST), barium titanate (BTO), and sodium potassium niobate (KNN).

In example 7, the subject matter of any of examples 1-6 can optionally include the ferroelectric capacitor being formed in-situ with a single organic dielectric layer of the plurality of organic dielectric layers.

In example 8, the subject matter of any of examples 1-7 can optionally include each electrode of the ferroelectric capacitor being formed with a horizontal configuration with the ferroelectric layer being disposed between the electrodes in a horizontal layer.

In example 9, the subject matter of any of examples 1-8 can optionally include each electrode of the ferroelectric capacitor being formed with an interdigitated configuration.

Example 10 is a microelectronic device that comprises a plurality of organic dielectric layers and first and second tunable ferroelectric capacitors formed in-situ with at least one organic dielectric layer of the plurality of organic dielectric layers. The first and second ferroelectric capacitors each include first and second conductive electrodes and a ferroelectric layer that is positioned between the first and second conductive electrodes.

In example 11, the subject matter of example 10 can optionally include an inductor that is electrically coupled to one of the first and second electrodes of each of the first and second tunable ferroelectric capacitors to provide a filter capacitor inductor capacitor (CLC) network.

In example 12, the subject matter of any of examples 10-11 can optionally include a first die coupled to one of the electrodes of the first ferroelectric capacitor and a second die coupled to one of the electrodes of the second ferroelectric capacitor.

In example 13, the subject matter of any of examples 10-11 can optionally include each ferroelectric capacitor that comprises a high-k ferroelectric capacitor having a tunable capacitance based on applying a voltage across the first and second electrodes to cause a change in polarization of the ferroelectric layer and thus a change in dielectric properties of the ferroelectric layer.

In example 14, the subject matter of any of examples 10-13 can optionally include the tunable capacitance of the ferroelectric capacitor that enables a reconfigurable microelectronic device.

In example 15, the subject matter of any of examples 10-14 can optionally include the ferroelectric layer that comprises at least one of ferroelectric material, ferroelectric perovskite, lead zirconate titanate (PZT), barium strontium titanate (BST), barium titanate (BTO), and sodium potassium niobate (KNN).

In example 16, the subject matter of any of examples 10-15 can optionally include each ferroelectric capacitor being formed with multiple ferroelectric layers disposed between multiple layers of the first electrode.

In example 17, the subject matter of any of examples 10-16 can optionally include each electrode of each ferroelectric capacitor being formed with an interdigitated configuration.

Example 18 is a computing device that comprises an integrated circuit die and a package substrate coupled to the integrated circuit die. The package substrate includes a plurality of organic dielectric layers and a tunable ferroelectric capacitor formed in-situ with at least one organic dielectric layer of the plurality of organic dielectric layers. The ferroelectric capacitor includes first and second conductive electrodes and a ferroelectric layer that is positioned between the first and second conductive electrodes.

In example 19, the subject matter of example 18 can optionally include an inductor that is electrically coupled to one of the first and second electrodes of the ferroelectric capacitor to provide a filter capacitor inductor (LC) network.

In example 20, the subject matter of any of examples 18-19 can optionally include the integrated circuit die that is coupled to one of the electrodes of the first ferroelectric capacitor.

In example 21, the subject matter of any of examples 18-20 can optionally include a printed circuit board coupled to the package substrate.

In example 22, the subject matter of any of examples 18-21 can optionally include the tunable ferroelectric capacitor being utilized in a tunable filter.

In example 23, the subject matter of any of examples 18-22 can optionally include the tunable ferroelectric capacitor being utilized in a tunable phase shifter.

What is claimed is:

1. A microelectronic device comprising:
a plurality of organic dielectric layers; and
a tunable ferroelectric capacitor formed in-situ with at least one organic dielectric layer of the plurality of organic dielectric layers, and the ferroelectric capacitor includes first and second conductive electrodes and a ferroelectric layer that is positioned between the first and second conductive electrodes.

2. The microelectronic device of claim 1, further comprising:
an inductor that is electrically coupled to one of the first and second electrodes.

3. The microelectronic device of claim 1, wherein the ferroelectric capacitor comprises a high-k capacitor having a tunable capacitance based on applying a voltage across the first and second electrodes to cause a change in polarization of the ferroelectric layer and thus a change in dielectric properties of the ferroelectric layer.

4. The microelectronic device of claim 1, wherein the tunable capacitance of the ferroelectric capacitor enables a reconfigurable microelectronic device.

5. The microelectronic device of claim 1, wherein the tunable capacitance of the ferroelectric capacitor has a tuning ratio of maximum capacitance to minimum capacitance that is approximately 1.01 to 3

6. The microelectronic device of claim 5, wherein the ferroelectric layer comprises at least one of ferroelectric material, ferroelectric perovskite, lead zirconate titanate (PZT), barium strontium titanate (BST), barium titanate (BTO), and sodium potassium niobate (KNN).

7. The microelectronic device of claim 1, wherein the ferroelectric capacitor is formed in-situ with a single organic dielectric layer of the plurality of organic dielectric layers.

8. The microelectronic device of claim 1, wherein each electrode of the ferroelectric capacitor is formed with a horizontal configuration with the ferroelectric layer being disposed between the electrodes in a horizontal layer.

9. The microelectronic device of claim 1, wherein each electrode of the ferroelectric capacitor is formed with an interdigitated configuration.

10. A microelectronic device comprising:
a plurality of organic dielectric layers; and
first and second tunable ferroelectric capacitors formed in-situ with at least one organic dielectric layer of the plurality of organic dielectric layers, and the first and second ferroelectric capacitors each including first and second conductive electrodes and a ferroelectric layer that is positioned between the first and second conductive electrodes.

11. The microelectronic device of claim 10, further comprising:
an inductor that is electrically coupled to one of the first and second electrodes of each of the first and second tunable ferroelectric capacitors to provide a filter capacitor inductor capacitor (CLC) network.

12. The microelectronic device of claim 10, further comprising:
a first die coupled to one of the electrodes of the first ferroelectric capacitor; and
a second die coupled to one of the electrodes of the second ferroelectric capacitor.

13. The microelectronic device of claim 10, wherein each ferroelectric capacitor comprises a high-k ferroelectric capacitor having a tunable capacitance based on applying a voltage across the first and second electrodes to cause a change in polarization of the ferroelectric layer and thus a change in dielectric properties of the ferroelectric layer.

14. The microelectronic device of claim 13, wherein the tunable capacitance of the ferroelectric capacitor enables a reconfigurable microelectronic device.

15. The microelectronic device of claim 10, wherein the ferroelectric layer comprises at least one of ferroelectric material, ferroelectric perovskite, lead zirconate titanate (PZT), barium strontium titanate (BST), barium titanate (BTO), and sodium potassium niobate (KNN).

16. The microelectronic device of claim 10, wherein each ferroelectric capacitor is formed with multiple ferroelectric layers disposed between multiple layers of the first electrode.

17. The microelectronic device of claim 10, wherein each electrode of each ferroelectric capacitor is formed with an interdigitated configuration.

18. A computing device comprising:
an integrated circuit die; and
a package substrate coupled to the integrated circuit die, the package substrate includes a plurality of organic dielectric layers and a tunable ferroelectric capacitor formed in-situ with at least one organic dielectric layer of the plurality of organic dielectric layers, and the ferroelectric capacitor includes first and second conductive electrodes and a ferroelectric layer that is positioned between the first and second conductive electrodes.

19. The computing device of claim 18, further comprising:
an inductor that is electrically coupled to one of the first and second electrodes of the ferroelectric capacitor to provide a filter capacitor inductor (LC) network.

20. The computing device of claim 18, wherein the integrated circuit die is coupled to one of the electrodes of the ferroelectric capacitor.

21. The computing device of claim 18, further comprising:
a printed circuit board coupled to the package substrate.

22. The computing device of claim 18, wherein the tunable ferroelectric capacitor is utilized in a tunable filter.

23. The computing device of claim 18, wherein the tunable ferroelectric capacitor is utilized in a tunable phase shifter.
